(19) United States
(12) Patent Application Publication
(10) Pub. No.: US 2024/0363327 A1
(43) Pub. Date: Oct. 31, 2024

(54) EPI THERMAL PROFILE TUNING WITH LAMP RADIATION SHIELDS

(71) Applicant: Applied Materials, Inc., Santa Clara, CA (US)

(72) Inventors: Zhepeng CONG, San Jose, CA (US); Ashur J. ATANOS, San Jose, CA (US); Nimrod SMITH, Cupertino, CA (US); Tao SHENG, Santa Clara, CA (US)

(21) Appl. No.: 18/308,776

(22) Filed: Apr. 28, 2023

(51) Int. Cl. H01K 1/26; C23C 16/46; C30B 25/10; F27B 17/00; H01K 7/00; H01L 21/67; H05B 3/00

(52) U.S. Cl. CPC H01K 1/26; C23C 16/46; C30B 25/105; F27B 17/0025; H01K 7/00; H01L 21/67115; H05B 3/0047

(57) ABSTRACT

Embodiments of the disclosure provided herein include an apparatus and method for lamp heating in process chambers used to process semiconductor substrates. The apparatus includes a lamp for use in a processing chamber, the lamp having a lamp envelope with an interior volume, a first end of the lamp envelope coupled to a base, a second end of the lamp envelope opposing the first end, a filament disposed within the interior volume, and a radiation shield proximate to the second end. In another embodiment, the lamp assembly has at least one lamp, the at least one lamp having a lamp envelope having an interior volume, a first end of the lamp envelope coupled to a base, a second end of the lamp envelope opposing the first end, a filament disposed within the interior volume, and a radiation shield proximate to the second end.

### BACKGROUND

### Field

Embodiments of the present disclosure generally relate to lamp heating in process chambers used to process semiconductor substrates. More specifically, the present disclosure relates to arrangement and control of lamps for heating of semiconductor substrates.

### Description of the Related Art

Epitaxial growth in semiconductor manufacturing involves growing a crystalline film on a substrate with a specific orientation. The epitaxial relationship between the film and the substrate is determined by the substrate used.

To achieve epitaxial growth, epitaxial chambers provide a controlled environment. These chambers are made of materials that are compatible with the growth process and can withstand high temperatures and vacuum conditions. During rapid thermal processing, lamps are often used as a radiation source, which heats a semiconductor substrate and emits the radiation necessary for the growth of the film. Different types of lamps can be used depending on the specific growth process requirements and film properties, however, the radiation sources may operate at elevated temperatures during substrate processing.

The radiation emitted by the lamps, may operate at temperatures high enough that could potentially damage the substrate or film. Accordingly, there is a need to for improved methods to prevent substrate and film damage in epitaxial chambers.

### SUMMARY

Embodiments described herein generally relate to lamp heating in process chambers used to process semiconductor substrates. More specifically, the present disclosure relates to arrangement and control of lamps for heating of semiconductor substrates.

In an embodiment, a lamp for use in a processing chamber, having a lamp envelope having an interior volume, a first end of the lamp envelope coupled to a base, a second end of the lamp envelope opposing the first end, a filament disposed within the interior volume, and a radiation shield proximate to the second end.

In another embodiment, a lamp assembly for use in a processing chamber, having at least one lamp, the at least one lamp having a lamp envelope having an interior volume, a first end of the lamp envelope coupled to a base, a second end of the lamp envelope opposing the first end, a filament disposed within the interior volume, and a radiation shield proximate to the second end.

In yet another embodiment, a substrate processing system, having a housing structure, a chamber having a processing volume having an upper chamber volume and a lower chamber volume, a substrate support disposed within the processing volume, an upper lamp module disposed within the chamber and having at least one lamp assembly, the at least one lamp assembly having a lamp envelope having an interior volume, a first end of the lamp envelope coupled to a base, a second end of the lamp envelope opposing the first end, a filament disposed within the interior volume, and a radiation shield proximate to the second end.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1A is a schematic cross-sectional view of a thermal processing chamber including an annular lamp array, according to certain embodiments.

FIG. 1B is a close-up schematic cross-sectional view of a portion of the thermal processing chamber illustrated in FIG. 1A, according to certain embodiments.

FIG. 2A is a schematic view of a lamp, according to certain embodiments.

FIG. 2B is a schematic view of a lamp, according to certain embodiments.

FIG. 3 is a top view of an annular lamp array, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to lamp heating in process chambers used to process semiconductor substrates. More specifically, the present disclosure relates to arrangement and control of lamps for heating of semiconductor substrates.

Epitaxial growth in an epitaxial chamber requires high temperatures and vacuum conditions. Lamps are used in epitaxial chambers to emit radiation necessary for growth of the film. The specific type of lamp used depends on the requirements of the growth process and the properties of the film being grown.

Traditional ways of epitaxial thermal profile tuning, such as the reflector or shield shape and surface finish, are currently used, but advanced nodes require finer thermal profile tuning for profile matching. The process of thermal profile tuning using reflectors and lamp sockets is challenging to control, particularly in targeting a specific region, such as the center of the substrate. This process involves changing the surface finish and shape of the shield, which can be relatively difficult to modify. Additionally, using a coating approach (e.g., adding a coating cap on a portion of the lamp) can degrade lamp life if the material cannot stand relative higher temperatures.

Accordingly, the present disclosure provides improved systems and methods for thermal profile tuning of the lamp radiation in an epitaxial chamber. The present disclosure describes epitaxial chamber lamps including a lamp radiation shield. The lamp radiation shield may be a disk made of a temperature-resistant material such as quartz. The radiation shield may be disposed on the outside tip of the lamp or on the inside tip of the lamp. A heat-resistant coating material may be applied to the tip of the lamp envelopes as an additional tuning knob to the radiation shield. The systems and methods described in the present disclosure allows for the fine-tuning of the thermal profile of lamp radiation, particularly at the center of the substrate where overlap occurs between lamp radiation zones. The shield material used in the present disclosure is compatible with infrared lamp construction, making it easy to perform fine-tuning of the thermal profile. Overall, the present disclosure provides a means of achieving a precisely controlled thermal profile, leading to improved results in the epitaxial process.

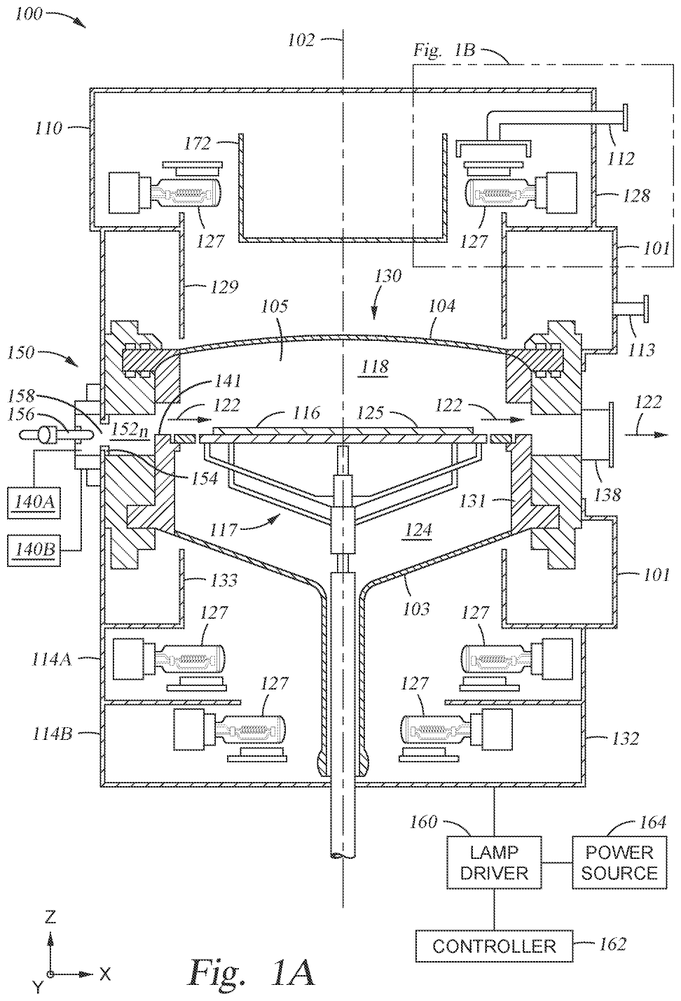

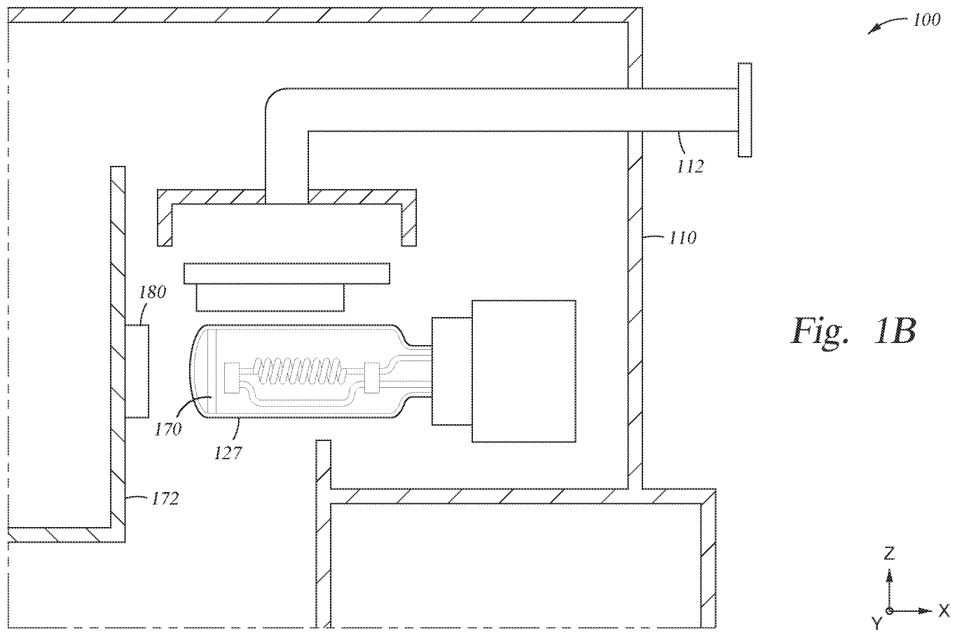

FIG. 1A is a schematic cross-sectional view of a deposition chamber 100. FIG. 1B is a close-up schematic cross-sectional view of an upper portion of the deposition chamber 100. The deposition chamber 100 may be a chemical vapor deposition (CVD) or epitaxial deposition chamber. The deposition chamber 100 includes a housing structure 101 made of a process resistant material, such as aluminum or stainless steel, for example 316 L stainless steel. The housing structure 101 encloses various functioning elements of the deposition chamber 100, such as a chamber 130, which may be quartz, and which includes an upper chamber volume 105, and a lower chamber volume 124, which together provide a processing volume 118. Reactive species are provided to the chamber 130 by a gas distribution assembly 150, and processing byproducts are removed from the processing volume 118 by an outlet port 138, which is typically in communication with a vacuum source (not shown).

A substrate support 117 is adapted to receive a substrate 125 that is transferred to the processing volume 118. The substrate support 117 is disposed along, and generally perpendicular to, a longitudinal axis 102 of the deposition chamber 100. The substrate support, which may be a susceptor, is made of a process resistant material such as ceramic, silicon carbide, or a graphite material coated with a silicon material, such as silicon carbide. Reactive species from precursor reactant materials are applied to a surface 116 of the substrate 125, and byproducts may be subsequently removed from the surface 116.

Heating of the substrate 125 and the processing volume 118 may be provided by radiation sources, such as an upper lamp module 110 and lower lamp modules 114A, 114B. The upper lamp module 110 and the lower lamp modules 114A, 114B are positioned adjacent to an upper divider 104 and a lower divider 103 respectively. Each of the dividers 103 and 104 may be a window, and each of the dividers 103 and 104 may be made of quartz. The upper lamp module 110, the lower lamp module 114A, and the lower lamp module 114B include a plurality of lamps 127. The lamps 127 in each of the lower lamp modules 114A, 114B, and the upper lamp module 110 may be any type of lamps suitable for semiconductor processing, for example, such as 2 kW lamps, 3 kW lamps, or the like.

The upper lamp module 110 includes a peripheral reflector structure 128, which provides for mechanical attachment of each lamp 127 with respect to the processing volume 118 as well as a reflective surface 129 to enhance directivity, distribution, or placement of radiation generated by each lamp 127. The lower lamp modules 114A, 114B also include a peripheral reflector structure 132, which provides for mechanical attachment of each lamp 127 with respect to the processing volume 118 as well as a reflective surface 133 to enhance directivity of radiation generated by each lamp 127. For the deposition chamber 100 of FIG. 1A, the peripheral reflector structure 128 and the peripheral reflector structure 132 may be formed from a rigid, thermally durable material such as aluminum or brass. Additionally, the reflective surfaces 129, 133 may be coated with a material having good reflective qualities for infrared radiation emitted by the lamps such as gold or copper.

Non-thermal energy or radiation from the upper lamp module 110 and the lower lamp modules 114A, 114B travels through the upper divider 104 of the upper chamber volume 105, and through the lower divider 103 of the lower chamber volume 124. During processing, the substrate 125 is disposed on the substrate support 117. The upper lamp module 110 and the lower lamp modules 114A, 114B are sources of radiation (e.g., radiant heat) and, in operation, generate a pre-determined temperature distribution across the substrate 125. Each of the lamp modules 110, 114A, and 114B may be divided into one or more lamp assemblies, where each lamp in a lamp assembly shares a specified characteristic.

As shown in FIG. 1B, each lamp 127 may include a radiation shield 170 further described below. A sensor 180 may be disposed facing a distal end of each of the lamps 127 proximate the radiation shield 170. The sensor 180 may be a direct temperature sensor such as a thermocouple, a photo sensor, or any other non-contact thermometry to determine the temperature of an isolation plate 172 and for coating detection.

The deposition chamber 100 further comprises one or more lamp drivers 160 to power the lamps of the lamp assemblies, a controller 162 for controlling the operation of the lamp driver 160, and one or more power sources 164 for powering the lamps in each lamp assembly via the one or more lamp drivers 160. The one or more lamp drivers 160 here transform AC power to DC power and step down the voltage of the DC power. The one or more lamp drivers 160 distribute the stepped-down power to a specified lamp assembly within each of the lamp modules 110, 114A, 114B. The configuration of the one or more lamp drivers 160 can vary dependent upon the type of lamp used. Although only one lamp driver 160 is shown, any number of lamp drivers, each corresponding to a lamp assembly or subgroup of lamps, which may be a subset of the lamps in a lamp assembly, in each of the lamp modules 110, 114A, and 114B, may be provided. The lamp driver may include at least one of a rectifier coupled with the AC power source to convert the AC input waveform to DC voltage and a direct-current to direct-current (DC/DC) converter to reduce the voltage of the DC power. The one or more power sources 164 are an alternating current (AC) power source to produce an AC input waveform or a direct current (DC) power source.

Cooling gases for the upper chamber volume 105, if needed, enter through an inlet port 112 and exit through an outlet port 113 of the reflector structure. Precursor reactant materials, as well as diluent, purge and vent gases for the deposition chamber 100, enter processing volume 118 through the gas distribution assembly 150 and exit therefrom through the outlet port 138. While the upper divider 104 is shown as being curved or convex, the upper divider 104 may be planar or concave.

The radiation in the processing volume 118, which is used to energize reactive species and assist in adsorption of reactants and desorption of process byproducts from the surface 116 of the substrate 125, typically ranges from about 0.8 μm to about 1.2 μm, for example, between about 0.95 μm to about 1.05 μm, with combinations of various wavelengths being provided, depending, for example, on the composition of the film.

The component gases enter the processing volume 118 via the gas distribution assembly 150. Gas flows from the gas distribution assembly 150 and exits through the outlet port 138 via a flow path as shown generally by arrow 122. Combinations of component gases, which are used to clean or passivate a substrate surface, or to grow the silicon or germanium-containing film, are typically mixed prior to entry into the processing volume. The overall pressure in the processing volume 118 may be adjusted by a valve (not shown) on the outlet port 138, which is pumped by a vacuum pump (not shown). At least a portion of the interior surface of the processing volume 118 is covered by a liner 131. The liner 131 may comprise a quartz material that is opaque. In this manner, the chamber wall is insulated from the heat in the processing volume 118.

The temperature of surfaces in the lamp module 110 may be controlled by the flow of a cooling gas, which enters through the inlet port 112 and exits through the outlet port 113, in combination with radiation from the upper lamp module 110 positioned above the upper divider 104. The temperature in the lower chamber volume 124 may be controlled within a temperature range of about 200° C. to about 600° C. or greater, by adjusting the speed of a blower unit, which is not shown, and by radiation from the lower lamp modules 114A, 114B disposed below the lower chamber volume 124. The pressure in the processing volume 118 may be between about 0.1 Torr to about 600 Torr, such as between about 5 Torr to about 30 Torr.

The temperature on the exposed surface 116 of the substrate 125 may be controlled by power adjustment to the lower lamp modules 114A, 114B in the lower chamber volume 124, or by power adjustment to both the upper lamp modules 110 overlying the upper chamber volume 105, and the lower lamp modules 114A, 114B in the lower chamber volume 124. The power density in the processing volume 118 may be between about 40 W/cm² to about 400 W/cm², such as about 80 W/cm² to about 120 W/cm².

The gas distribution assembly 150 may be disposed normal to, or in a radial direction 106 relative to, the longitudinal axis 102 of the deposition chamber 100 or the substrate 125. In this orientation, the gas distribution assembly 150 is adapted to flow process gases in a radial direction 106 across, or parallel to, the surface 116 of the substrate 125. In one processing application, the process gases are preheated at the point of introduction to the deposition chamber 100 to initiate preheating of the gases prior to introduction to the processing volume 118, and/or to break specific bonds in the gases. In this manner, surface reaction kinetics may be modified independently from the thermal temperature of the substrate 125.

In operation, precursors to form Si and SiGe blanket or selective films are provided to the gas distribution assembly 150 from one or more gas sources 140A and 140B. The gas sources 140A, 140B may be coupled to the gas distribution assembly 150 in a manner configured to facilitate introduction zones within the gas distribution assembly 150, such as a radial outer zone to introduce gas over the outer circumferential portion thereof and a radial inner zone between the outer zones when viewed in from a top plan view, to introduce gas directed toward the center of the substrate. The gas sources 140A, 140B may include valves (not shown) to control the rate of introduction into the zones.

The gas sources 140A, 140B may include silicon precursors such as silanes, including silane (SiH₄), disilane (Si₂H₆), dichlorosilane (SiH₂Cl₂), hexachlorodisilane (Si₂Cl₆), dibromosilane (SiH₂Br₂), higher order silanes, derivatives thereof, and combinations thereof. The gas sources 140A, 140B may also include germanium-containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCl), chlorine gas (Cl₂), hydrogen bromide (HBr), and combinations thereof. The gas sources 140A, 140B may include one or more of the silicon and germanium containing precursors in one or both of the gas sources 140A, 140B.

The precursor materials enter the processing volume 118 through openings or a plurality of holes 158 (only one is shown in FIG. 1A) in a perforated plate 154 in this excited state, such as a quartz material, having the holes 158 formed therethrough. The perforated plate 154 may be made of a clear quartz material. The perforated plate 154 may be any material that is resistant to process chemistry and other process chemistries. The energized precursor materials flow toward the processing volume 118 through the plurality of holes 158 in the perforated plate 154, and through a plurality of channels 152 (only one is shown in FIG. 1A).

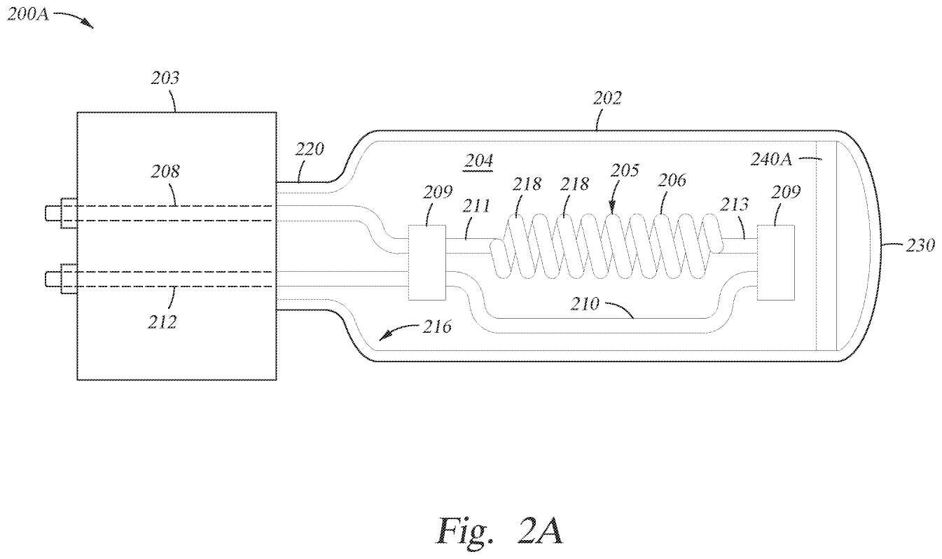

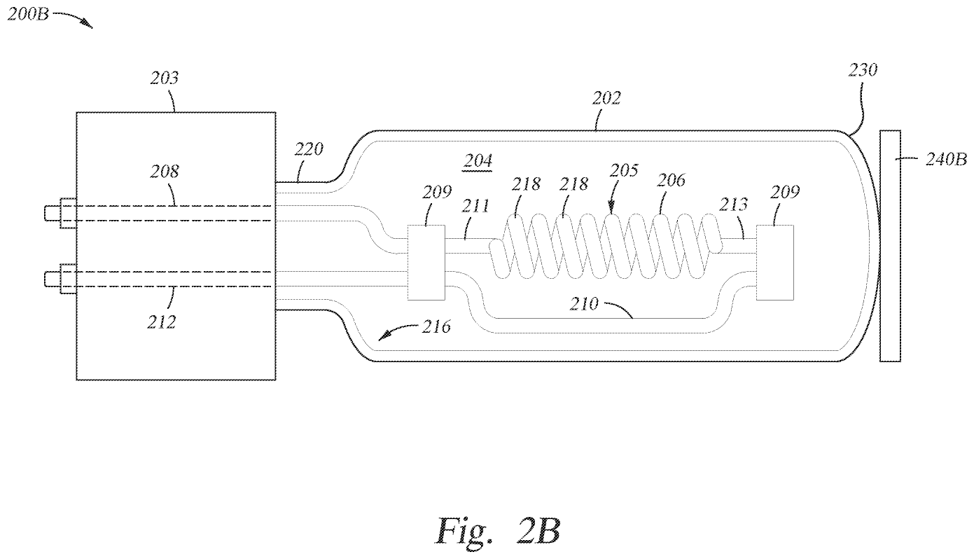

FIG. 2A is a schematic view of one example of a lamp 200A. The lamp 200A may be used in place of any of the lamps described herein, e.g., lamps 127 of FIG. 1A. The lamp 200A may generally comprise a lamp envelope 202 having interior volume 204. The lamp envelope 202 may be formed of a transparent or semi-transparent material, such as quartz, glass, or other suitable materials. The lamp envelope 202 has a first end 220 coupled with a base 203 and a second end 230 opposing the first end 220.

A filament 206 is disposed within the interior volume 204 to provide heat energy when electric current is provided to the filament 206 of the lamp 200A. The filament 206 includes a main body 205 disposed between a first end 211 and a second end 213 of the filament 206. The filament 206 is coupled at the first end 211 to a first conductor 208. The filament 206 may be supported by one or more support structures (not shown) which extend from one or more support bases 209 disposed within the interior volume 204.

A radiation shield 240A may be disposed within the interior volume 204 at a distal end of the lamp 200A proximate to the second end 230, such that the radiation shield 240A is positioned between the filament 206 and the second end 230. The radiation shield 240A may comprise a high-temperature compatible material composition, such as an opaque quartz, a molybdenum foil, or other refractory metal foils or high-temperature, low emissivity ceramics. The radiation shield 240A reduces the radiation emitted by the filament 206, allowing for finer thermal profile tuning of the substrate (e.g., substrate 125 of FIG. 1A) while preserving the lamp lifetime.

A first interceptor bar 210, which is conductive, may be disposed within the lamp envelope 202 beneath the filament 206. The first interceptor bar 210 may be coupled between the second end 213 of the filament 206 and a second conductor 212. During typical operation, current flows into the lamp via the first conductor 208, through the filament 206, along the first interceptor bar 210, and exits the lamp via the second conductor 212.

The filament 206 may comprise a tightly coiled wire that is then wrapped into a plurality of coils 218. The plurality of coils 218 may form the main body 205 of the filament 206. However, other configurations of the filament are possible, such as loops, helices, or other suitable coil-like configurations. An increased length, and current path, of the filament, by for example, providing coils 218 and secondary coils (not shown), can increase resistance through the filament 206, which can allow the lamp to operate at lower currents. The filament 206 may be formed of tungsten or another suitable filament material.

The interior volume 204 may be filled with an inert gas, for example, argon, helium, or the like, and further with a halogen gas, such as bromine or hydrogen bromide. When present, during use of the lamp 200A, the halogen gas may prevent deposition of the filament material on interior surfaces 216 of the lamp envelope 202 by facilitating re-deposition of the filament material on the filament 206.

The lamp 200A may further include the base 203 having the first and second conductors 208, 212 disposed therethrough. The base 203 may provide support to the lamp 200A, such as by being held in a socket assembly or other similar structure. The base 203 may be fabricated from any non-conductive material suitable to provide support to the lamp, for example a ceramic such as aluminum oxide (Al₂O₃) or the like.

FIG. 2B is a schematic view of an example of a lamp 200B. The lamp 200B is configured similarly to lamp 200A except as otherwise described. The lamp 200B may be used in place of any of the lamps described herein, e.g., lamps 127 of FIG. 1A. The lamp 200B may generally comprise a lamp envelope 202 having interior volume 204. The lamp envelope 202 has a first end 220 coupled with a base 203 and a second end 230 opposing the first end 220.

A filament 206 is disposed within the interior volume 204 of the lamp 200B. The filament 206 includes a main body 205 disposed between a first end 211 and a second end 213 of the filament 206. The filament 206 is coupled at the first end 211 to a first conductor 208. The filament 206 may be supported by one or more support structures (not shown) which extend from one or more support bases 209 disposed within the interior volume 204.

A radiation shield 240B may be coupled to an outer surface of the second end 230, such that the second end 230 is positioned between the filament 206 and the radiation shield 240B. The radiation shield 240B may comprise a high-temperature compatible material composition, such as an opaque quartz, a reflective quartz, or other refractory metal foils or high-temperature, low emissivity ceramics. The radiation shield 240B in this configuration reduces the radiation emitted by the filament 206, allowing for finer thermal profile tuning of the substrate (e.g., substrate 125) while allowing easier manufacturing of the lamp 200B.

A first interceptor bar 210, which is conductive, is disposed within the lamp envelope 202 beneath the filament 206. As used, herein, beneath means both directly beneath or at an angle to (e.g., below and to a side of) the filament 206, so long as the filament may contact the first interceptor bar 210 when sagging to a sufficient degree during use or over time, and is not intended to limit orientation of the lamp 200B. The first interceptor bar 210 may be coupled between the second end 213 of the filament 206 and a second conductor 212. During typical operation, current flows into the lamp via the first conductor 208, through the filament 206, along the first interceptor bar 210, and exits the lamp via the second conductor 212.

The filament 206 may comprise a tightly coiled wire that is then wrapped into a plurality of coils 218. The plurality of coils 218 may form the main body 205 of the filament 206. However, other configurations of the filament are possible, such as loops, helices, or other suitable coil-like configurations. An increased length, and current path, of the filament, by for example, providing coils 218 and secondary coils (not shown), can increase resistance through the filament 206, which can allow the lamp to operate at lower currents. The filament 206 may be formed of tungsten or another suitable filament material.

The interior volume 204 may be filled with an inert gas, for example, argon, helium, or the like, and further with a halogen gas, such as bromine or hydrogen bromide. When present, during use of the lamp 200B, the halogen gas may prevent deposition of the filament material on interior surfaces 216 of the lamp envelope 202 by facilitating re-deposition of the filament material on the filament 206.

The lamp 200B may further include the base 203 having the first and second conductors 208, 212 disposed therethrough. The base 203 may provide support to the lamp 200B, such as by being held in a socket assembly or other similar structure. The base 203 may be fabricated from any non-conductive material suitable to provide support to the lamp, for example a ceramic such as aluminum oxide (Al₂O₃) or the like.

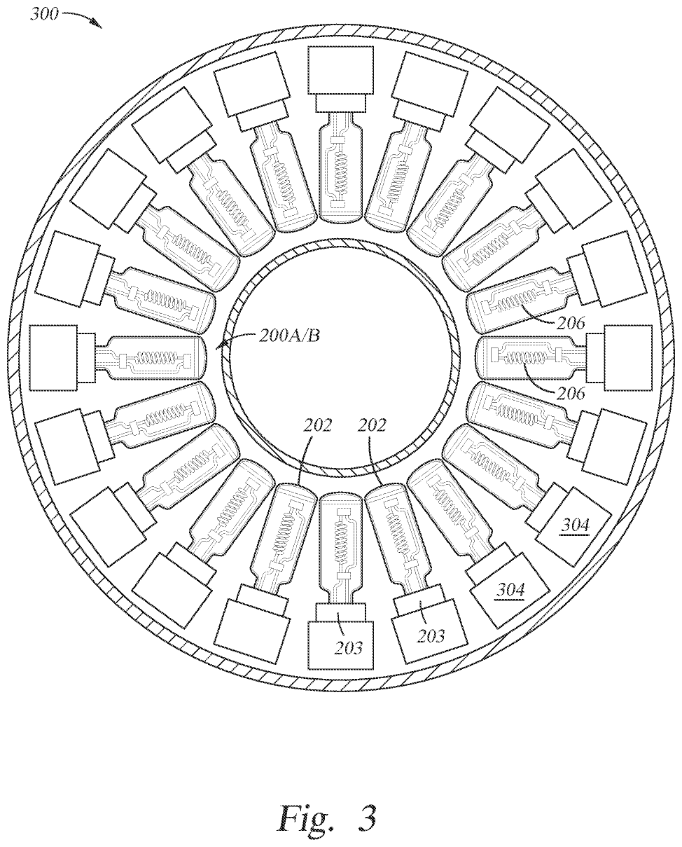

FIG. 3 is a top view of an annular lamp array 300. One or more lamps 200A/B (e.g., lamps in lamp modules 110, 114A, 114B described above) are arranged or configured in any manner suitable to provide a targeted temperature profile within a process chamber (e.g., deposition chamber 100 described above) to facilitate a process within the deposition chamber. For example, one or more of a group of the lamps 200A/B in the upper lamp module 110 or the lower lamp modules 114A, 114B are arranged in an array, such as the annular array as depicted in FIG. 3. Each lamp 200A/B of the annular lamp array 300 of lamps may be coupled with a respective socket 304 to provide power to the lamp 200A/B. The socket 304 is supported by, or coupled with, any portion of the process chamber, for example such as the peripheral reflector structure 128 or the peripheral reflector structure 132 described above, or in any other suitable location to position the lamps 200A/B as chosen to facilitate providing the heat energy from the lamps 200A/B to the process chamber during use. The lamps 200A/B within the array are divided into separately controllable lamp assemblies or subgroups as further described herein.

The present disclosure enables the fine-tuning of the thermal profile of lamp radiation for improved results in the epitaxial growth process. The present disclosure involves the use of a compatible reflector material for infrared lamp construction, simplifying the fine-tuning of the thermal profile. The resulting benefits include a precisely controlled thermal profile, particularly at the center of the substrate where overlap occurs between lamp radiation zones.

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a fist object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A lamp for use in a processing chamber, comprising:
a lamp envelope having an interior volume;
a first end of the lamp envelope coupled to a base;
a second end of the lamp envelope opposing the first end;
a filament disposed within the interior volume; and
a radiation shield proximate to the second end.

2. The lamp of claim 1, wherein the radiation shield is disposed within the interior volume of the lamp envelope positioned between the filament and the second end.

3. The lamp of claim 2, wherein the radiation shield comprises an opaque quartz material or a molybdenum foil.

4. The lamp of claim 1, wherein the radiation shield is coupled to an outer surface of the second end such that the second end is positioned between the filament and the radiation shield.

5. The lamp of claim 4, wherein the radiation shield comprises an opaque quartz or a reflective quartz.

6. A lamp assembly for use in a processing chamber, comprising:
at least one lamp, the at least one lamp comprising:
a lamp envelope having an interior volume;
a first end of the lamp envelope coupled to a base;
a second end of the lamp envelope opposing the first end;
a filament disposed within the interior volume; and
a radiation shield proximate to the second end.

7. The lamp assembly of claim 6, wherein the radiation shield is disposed within the interior volume of the lamp envelope positioned between the filament and the second end.

8. The lamp assembly of claim 7, wherein the radiation shield comprises an opaque quartz material or a molybdenum foil.

9. The lamp assembly of claim 6, wherein the radiation shield is coupled to an outer surface of the second end such that the second end is positioned between the filament and the radiation shield.

10. The lamp assembly of claim 9, wherein the radiation shield comprises an opaque quartz or a reflective quartz.

11. The lamp assembly of claim 6, further comprising an annular array of a plurality of the at least one lamp disposed within an upper lamp module of a substrate processing system.

12. The lamp assembly of claim 11, the annular array configured to heat a processing volume of the substrate processing system, a substrate on a substrate support, or both.

13. The lamp assembly of claim 6, further comprising an annular array of a plurality of the at least one lamp disposed within a lower lamp module of a substrate processing system.

14. A substrate processing system, comprising:
a housing structure;
a chamber comprising a processing volume comprising an upper chamber volume and a lower chamber volume;
a substrate support disposed within the processing volume;
an upper lamp module disposed within the chamber and comprising at least one lamp assembly, the at least one lamp assembly comprising:
a lamp envelope having an interior volume;
a first end of the lamp envelope coupled to a base;
a second end of the lamp envelope opposing the first end;
a filament disposed within the interior volume; and
a radiation shield proximate to the second end.

15. The substrate processing system of claim 14, wherein the radiation shield is disposed within the interior volume of the lamp envelope positioned between the filament and the second end.

16. The substrate processing system of claim 15, wherein the radiation shield comprises an opaque quartz material or a molybdenum foil.

17. The substrate processing system of claim 14, wherein the radiation shield is coupled to an outer surface of the second end such that the second end is positioned between the filament and the radiation shield.

18. The substrate processing system of claim 17, wherein the radiation shield comprises an opaque quartz or a reflective quartz.

19. The substrate processing system of claim 14, further comprising a sensor proximate to the radiation shield, the sensor configured to determine a temperature of an isolation plate.

20. The substrate processing system of claim 14, wherein the lamp assembly is configured to heat the processing volume, a substrate on the substrate support, or both.
